(19) United States
(12) Patent Application Publication
(10) Pub. No.: US 2025/0336715 A1
(43) Pub. Date: Oct. 30, 2025

(54) BIAS MODULATION FOR MOLYBDENUM OXIDE REDUCTION IN BEOL

(71) Applicant: Applied Materials, Inc., Santa Clara, CA (US)

(72) Inventors: Jiajie CEN, Santa Clara, CA (US); Ruinan ZHOU, Santa Clara, CA (US); Suhas UMESH, Santa Clara, CA (US); Hsien-Lung YANG, Santa Clara, CA (US); Tianyi SUN, Santa Clara, CA (US)

(21) Appl. No.: 18/645,570

(22) Filed: Apr. 25, 2024

(51) Int. Cl. H01L 21/768; H01J 37/32; H01L 21/02

(52) U.S. Cl. CPC H01L 21/76814; H01J 37/32091; H01J 37/32568; H01L 21/02068; H01J 2237/335

(57) ABSTRACT

Embodiments herein are generally directed to systems and methods for removing metal oxide layers for back-end-of-line processes. A substrate processing system includes a processing chamber configured to generate a plasma within the processing chamber, a substrate electrode embedded within a substrate support assembly disposed within the processing chamber, a radio frequency (RF) generator assembly coupled to the substrate electrode, and a controller. The controller is configured to flow a cleaning gas over a surface of a substrate support disposed within a processing chamber and generate a radio frequency (RF) pulsed bias that delivers an RF waveform for a first portion of a pulse period and halts the delivery of the RF waveform for a second portion of the pulse period and apply the RF pulsed bias to the substrate electrode while the plasma is present in the processing chamber.

### BACKGROUND

### Field

Embodiments of the present disclosure generally relate to systems and methods of semiconductor manufacturing, and, more particularly, to systems and methods of removing metal oxide layers.

### Description of the Related Art

In semiconductor manufacturing, Back End of Line (BEOL) processes involve the creation of interconnects, insulating layers, and metallization to connect the various components of the integrated circuit (IC) together, such as transistors, capacitors, resistors.

Molybdenum is used as filling contact metal in middle of line (MOL). Prior to BEOL processes, the substrates undergo a pre-clean process in a pre-clean chamber to remove any chemical residues or oxides which may have formed while the substrate is exposed to atmosphere. Excessive oxidation of a molybdenum surface increases the contact resistance, and subsequently degrades the electrical performance of the interconnects which leads to higher power consumption or signal attenuation.

Dry etching, such as reactive-ion etching, can selectively remove molybdenum oxide from a substrate. The process involves creating a plasma using reactive gases. A radio frequency (RF) power supply creates an electromagnetic field that ionizes the gas to create a plasma. The plasma contains high-energy ions that strike the substrate surface and react with it. The RF power supply for a removing material is applied as a continuous wave (CW), where the RF bias voltage is applied continuously throughout the treatment process resulting in continuous bombardment the surface of the substrate. This degrades the dielectric constant (k) of low-k substrates and is inefficient in removing molybdenum oxide layers from the molybdenum structures on the surface of the substrate.

Accordingly, there is a need for improved systems and methods to remove molybdenum oxide for BEOL processes.

### SUMMARY

Embodiments herein are generally directed to systems and methods of semiconductor manufacturing and, more particularly, to systems and methods for removing metal oxide layers for back-end-of-line processes.

In an embodiment, a substrate processing system is provided. The substrate processing system includes a processing chamber having a dielectric lid, an inductive coil disposed about the dielectric lid and configured to generate a plasma within the processing chamber, a substrate electrode embedded within a substrate support assembly disposed within the processing chamber, a radio frequency (RF) generator assembly coupled to the substrate electrode, and a controller coupled to the processing chamber and configured to flow a cleaning gas over a surface of a substrate support disposed within a processing chamber, generate a radio frequency (RF) pulsed bias using an RF bias generator of the RF generator assembly. The RF pulsed bias includes delivering an RF waveform for a first portion of a pulse period and halting the delivery of the RF waveform for a second portion of the pulse period, deliver an RF signal from an RF power source coupled to the inductive coil to form a plasma over the surface of the substrate support, and apply the RF pulsed bias to the substrate electrode within the substrate support assembly while the plasma is present in the processing chamber.

In another embodiment, a substrate processing system is provided. The substrate processing system includes a processing chamber configured to form a capacitively coupled plasma and including an upper electrode coupled to a first radio frequency (RF) generator assembly, a substrate electrode embedded within a substrate support and facing the upper electrode, a processing volume between the upper electrode and the substrate electrode, a second RF generator assembly coupled to the substrate electrode, and a controller coupled to the radio frequency generator assembly and configured to flow a cleaning gas over a surface of a substrate support disposed within a processing chamber, deliver an RF signal from the first RF generator assembly coupled to the upper electrode to form a plasma over the surface of the substrate support, generate an RF pulsed bias using an RF bias generator of the second RF generator assembly. The RF pulsed bias includes delivering an RF waveform for a first portion of a pulse period and halting the delivery of the RF waveform for a second portion of the pulse period, and apply the RF pulsed bias to the substrate electrode within the substrate support while the plasma is present in the processing chamber.

In yet another embodiment, a method of processing a substrate is provided. The method includes flowing a cleaning gas or cleaning plasma onto a substrate disposed on a substrate support assembly of a processing chamber, and applying a radio frequency (RF) pulsed bias to the substrate support assembly while the cleaning gas or cleaning plasma is present in the processing chamber. The RF pulsed bias includes delivering an RF waveform for a first portion of a pulse period and halting the delivery of the RF waveform for a second portion of the pulse period.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 illustrates a schematic, cross-sectional view of a substrate processing system, according to certain embodiments.

FIG. 2 illustrates a schematic, cross-sectional view of a substrate processing system, according to certain embodiments.

FIG. 3A illustrates a pulsing pattern generated by a plasma generator assembly, according to certain embodiments.

FIG. 3B illustrates a pulsing frequency of the pulsing pattern of FIG. 3A, according to certain embodiments.

FIG. 4 illustrates a method of removing a metal oxide during a BEOL pre-clean process, according to certain embodiments.

FIGS. 5A-5D illustrates a schematic, cross-sectional view of a substrate undergoing the method of FIG. 4, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to systems and methods of semiconductor manufacturing and, more particularly, to systems and methods for removing metal oxide layers for back-end-of-line processes.

In semiconductor manufacturing, middle-of-line (MOL) and back-end-of-line (BEOL) refers to stages of processing that occurs after the front-end processes have been performed. MOL and BEOL processes involve the creation of interconnects, insulating layers, and metallization to connect the various components of the integrated circuit (IC) together, such as transistors, capacitors, resistors. The interconnects and metallization often involves the deposition of various different types of metals such as, molybdenum, tungsten, cobalt, titanium, tantalum and copper onto features formed on a substrate.

For the first layer in BEOL, a good contact between the filling metal used in MOL, such as molybdenum, and the filling metal used in BEOL, such as copper, is required to minimize issues caused by high contact resistance between the two metals. Before proceeding with the BEOL processes, which includes deposition of copper, the surface of deposited molybdenum needs to be cleaned as exposure of the surface of the molybdenum to atmosphere has caused the formation of a layer of molybdenum oxide.

Oxidation can compromise the resistance at the interface for the first contacting layer in BEOL, which may also affect subsequent processes. Insufficient removal of molybdenum oxide can cause an unwanted resistance-capacitance (RC) delay degrading the performance of completed devices. Thus, an effective oxide reduction method is required to remove or reduce the oxide layer from the molybdenum surface deposited from MOL before proceeding with BEOL processes.

Dry etching, such as reactive-ion etching can selectively remove molybdenum oxide from a substrate. The process involves creating a plasma using reactive gases, e.g., fluorocarbons, oxygen, chlorine, boron trichloride, or hydrogen. The ions in the plasma bombard the Molybdenum oxide layer and dislodge or react with molybdenum oxide atoms from the surface of the substrate.

A radio frequency (RF) power supply is required to create the plasma necessary for material removal. The RF power supply creates an electromagnetic field that ionizes the gas molecules in the chamber by stripping them of electrons. This ionization creates a plasma. The plasma contains high-energy ions that attack the wafer surface and react with it. These ions are responsible for the material removal. The RF power supply typically operates between 13.56 MHz and 27.12 MHz and is applied at a few hundred watts. The RF power supply for a removing material is applied as a continuous wave (CW), where the RF bias voltage is applied continuously throughout the treatment process. The RF bias voltage applied continuously will, in turn, continuously excite gas molecules that bombard the surface of the substrate. This continuous bombardment degrades the dielectric constant (k) of low-k substrates and is inefficient in removing molybdenum oxide layers from the molybdenum structures on the surface of the substrate.

The present disclosure provides for systems and methods for removing molybdenum oxide layers from molybdenum structures during a MEOL or BEOL process. In particular, the systems and methods include applying an RF bias to a substrate support, via an embedded substrate electrode, where the RF bias includes a pulsing pattern that has a duty cycle or pulse period. The duty cycle includes a first portion, a bias ON period, where the RF bias is applied to the substrate electrode and a second portion, a bias OFF period, where no bias is applied to the substrate electrode. The bias ON period excites the cleaning gas ions to remove the molybdenum oxide while the bias OFF period allows for efficient removal of by-products from the bias ON period. This pulsing pattern allows for improved molybdenum oxide removal and preserves the dielectric constant of low-k substrates.

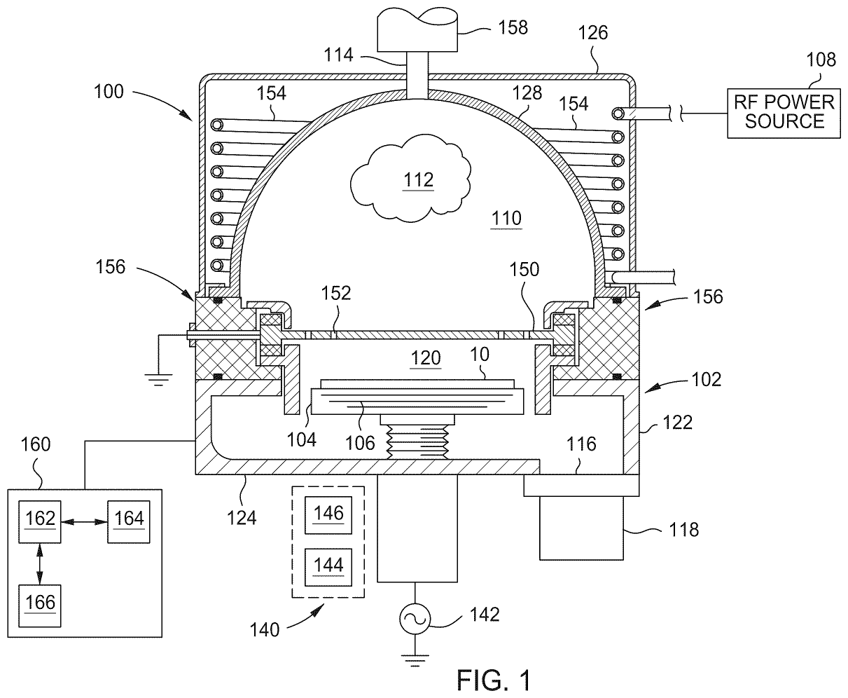

FIG. 1 a schematic, cross-sectional view of a substrate processing system 100. The substrate processing system 100 is configured to generate an inductively-coupled plasma and may be a pre-clean processing system. The substrate processing system 100 comprises a processing chamber 102 having a first volume 110 and a second volume 120. The first volume 110 may include a portion of the processing chamber 102 where a plasma 112 is to be received (e.g., introduced or formed). The second volume 120 may include a portion of the processing chamber 102 where a substrate 10 is to be processed with plasma species from the plasma 112. For example, a substrate support 104 having a substrate electrode 106 may be disposed within the second volume 120 of the processing chamber 102. A gas distribution plate 150, which is electrically grounded, may be disposed in the processing chamber 102 between the first volume 110 and the second volume 120 such that the plasma 112 formed in the first volume 110 (or plasma species formed from the plasma 112) can only reach the second volume 120 by passing through apertures 152 of the gas distribution plate 150. Plasma species formed in the plasma 112 may include, but are not limited to, ions, electrons, reactants, or combinations thereof. Alternatively, the substrate processing system 100 may not include the gas distribution plate 150, e.g., the first volume 110 and the second volume 120 are merged. In such embodiments, the plasma 112 may reach the substrate 10 unobstructed.

The substrate processing system 100 may include a gas inlet 114 coupled to the process chamber 102 to provide one or more processes gases from a process gas supply line 158 that may be used to form a plasma 112 in the first volume 110. A gas exhaust 116 may be coupled to the processing chamber 102, e.g., in a lower portion of the process chamber 102 including the second volume 120. The gas exhaust 116 is coupled to a pump 118 configured to create a negative pressure difference in the second volume 120 such that gases in the second volume 120 are evacuated from the process chamber 102. In some embodiments, an RF power source 108 may be coupled to an inductive coil 154 to generate the plasma 112 within the processing chamber 102. Alternatively, the plasma may be generated remotely, for example, by a remote plasma source (not shown) and flowed into the first volume 110 of the process chamber 102. In some embodiments, an RF generator assembly 140 may be coupled to the substrate electrode 106 of the substrate support 104 to control ion flux to the substrate 10 when present on a surface of the substrate support 104. The RF generator assembly 140 includes an RF bias generator 142 that is coupled to an RF matching circuit 144 and a filter assembly 146.

The process chamber 102 includes walls 122, a bottom 124, and a top 126. A dielectric lid 128 may be disposed under the top 126 and above a process kit 156, the process kit 156 coupled to the processing chamber 102 and configured to hold the gas distribution plate 150. The dielectric lid 128 may be dome-shaped as shown in FIG. 1. The dielectric lid 128 be made from dielectric materials, such as glass or quartz, and is typically a replaceable part that may be replaced after a certain number of substrates have been processed in the substrate processing system 100. The inductive coil 154 may be disposed about the dielectric lid 128 and coupled to an RF power source 108 to inductively couple RF power to the first volume 110 to form the plasma 112 in the first volume 110. Alternatively or in combination with the inductive coil 154, a remote plasma source (not shown) may be used to form the plasma 112 in the first volume 110 or to provide the plasma 112 to the first volume 110.

The process kit 156 rests on the wall 122 of the processing chamber 102. The process kit 156 may comprise any suitable materials compatible with processes being run in the substrate processing system 100. The components of the process kit 156 may contribute to defining the first volume 110 and the second volume 120. For example, the first volume 110 is defined by the upper surface of the gas distribution plate 150 and the inner surface of the dielectric lid 128. For example, the second volume 120 may be defined the lower surface of the gas distribution plate 150 and the substrate supporting surface of the substrate support 104.

The substrate processing system 100 may include a controller 160 to control one or more components of the substrate processing system 100 to perform operations on the substrate 10. The controller 160 generally includes the central processing unit (CPU) 162, the memory 164, and the support circuits 166. The CPU 162 may be one of any form of a general purpose processor that can be used in an industrial setting. The memory 164, or non-transitory computer-readable medium, is accessible by the CPU 162 and may be one or more of memory such as random access memory (RAM), read only memory (ROM), floppy disk, hard disk, or any other form of digital storage, local or remote. The support circuits 166 are coupled to the CPU 162 and may comprise cache, clock circuits, input/output subsystems, power supplies, and the like. The various methods disclosed herein may generally be implemented under the control of the CPU 162 by the CPU 162 executing computer instruction code stored in the memory 164 (or in memory of a particular processing chamber) as, for example, a software routine. When the computer instruction code is executed by the CPU 162, the CPU 162 controls the processing chambers to perform processes in accordance with the various methods.

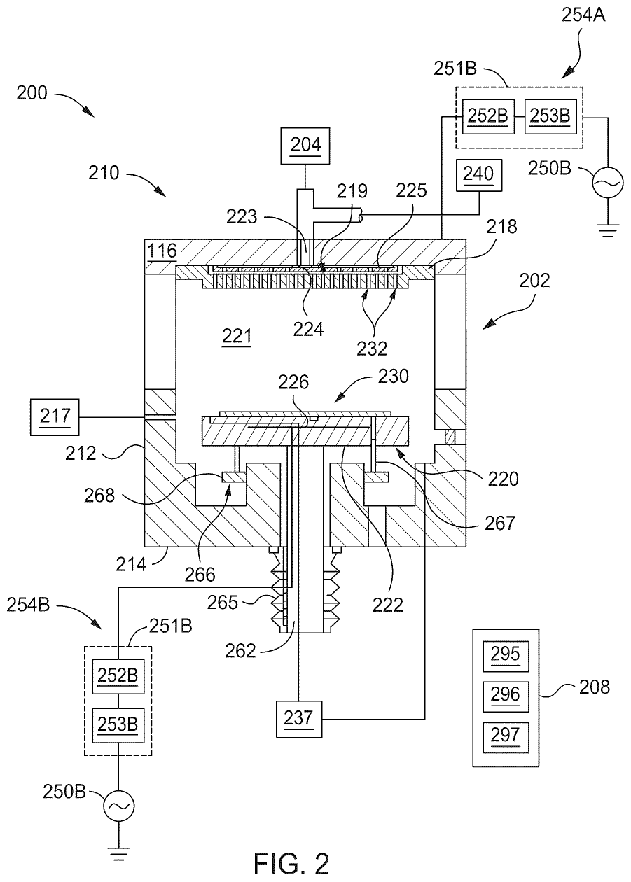

FIG. 2 illustrates a substrate processing system 200 configured to generate a capacitively-coupled plasma that may be used for pre-clean methods, including plasma etching. The substrate processing system 200 includes a processing chamber 202, a gas delivery system 204 fluidly coupled to the processing chamber 202, and a system controller. The processing chamber 202 includes a chamber lid assembly 210, one or more sidewalls 212, and a chamber base 214, which collectively define a processing volume 221. The processing volume 221 is fluidly coupled to an exhaust 217, such as one or more vacuum pumps, used to maintain the processing volume 221 at sub-atmospheric conditions and to evacuate processing gases and processing by-products therefrom.

The chamber lid assembly 210 includes a lid plate 216 and a showerhead 218 coupled to the lid plate 216 to define a gas distribution volume 219. The showerhead 218 faces a substrate support assembly 220 disposed in the processing volume 221. The substrate support assembly 220 is configured to move a substrate support 222 between a raised substrate processing position (as shown) and a lowered substrate transfer position (not shown).

The gas delivery system 204 is fluidly coupled to the processing chamber 202 through at least one gas inlet 223 that is disposed through the lid plate 216, one or more sidewalls 212, or both (both shown). Processing or cleaning gases delivered by the gas delivery system 204 may flow through the at least one gas inlet 223 in the lid plate 216 and a baffle 224 into the gas distribution volume 219 and are distributed into the processing volume 221 through a plurality of openings 232 in the showerhead 218. The chamber lid assembly 210 further includes a perforated diffusion plate 225 disposed between the at least one gas inlet 223 in the lid plate 216 and the showerhead 218. The gases flowed into the gas distribution volume 219 are first diffused by the perforated diffusion plate 225 to provide a more uniform or desired distribution of gas flow into the processing volume 221. Cleaning gases can also be delivered through the at least one gas inlet 223 in the one or more sidewalls 212 and into the processing volume 221. Processing gases and processing by-products are evacuated from the processing volume 221 through openings in the one or more sidewalls 212.

A purge gas source 237 in fluid communication with the processing volume 221 is used to flow a chemically inert purge gas, such as argon (Ar) or helium (He), into a region disposed beneath the substrate support 222, e.g., through the opening in the chamber base 214 surrounding a movable support shaft 262 supporting the substrate support 222. The purge gas may be used to create a region of positive pressure below the substrate support 222 when compared to the pressure in the processing volume 221 during substrate processing. Typically, purge gas introduced through the chamber base 214 flows up and around the edges of the substrate support 222 to be evacuated from the processing volume 221 through openings in the one or more sidewalls 212.

The substrate support assembly 220 includes the movable support shaft 262 that may be surrounded by a bellows 265. The substrate support assembly 220 includes a lift pin assembly 266 comprising a plurality of lift pins 267 coupled to a lift pin hoop 268. The plurality of lift pins 267 are movably disposed in openings formed through the substrate support 222. When the substrate support 222 is disposed in a lowered substrate transfer position (not shown), the plurality of lift pins 267 extend above a substrate receiving surface of the substrate support 222 to lift a substrate 230 and provide access to a backside surface of the substrate 230. When the substrate support 222 is in a raised or processing position, the plurality of lift pins 267 recede beneath the substrate receiving surface of the substrate support 222 to allow the substrate 230 to rest thereon. The plurality of lift pins 267 may lift the substrate 230 during processing, such as during a remote plasma source cleaning process or an RF capacitively coupled cleaning process, such that cleaning gases and cleaning plasma may flow on opposing sides of the substrate 230, e.g., the front side and the backside of the substrate 230.

As shown, the substrate processing system 200 may be configured to form a capacitively coupled plasma (CCP), including an upper electrode (e.g., lid plate 216) disposed adjacent the processing volume 221 facing a lower electrode (e.g., substrate support assembly 220) disposed in the processing volume 221 opposite the upper electrode. A first plasma generator assembly 254A includes a first RF generator 250A and a first RF generator assembly 251A, and is electrically coupled to the upper electrode to deliver an RF signal configured to ignite and maintain a plasma. The first RF generator 250A includes a first RF matching circuit 253A and a first filter assembly 252A disposed within the first RF generator assembly 251A. Alternatively, the showerhead 218 may be electrically coupled to the first RF generator 250A to ignite and maintain a plasma of processing gases flowed into the processing volume 221 through capacitive coupling therewith.

The lower electrode (e.g., the substrate support assembly 220) is coupled to a second RF generator assembly 254B. As shown in FIG. 2, one or more components of the substrate support assembly 220, such as a substrate electrode 226 embedded in the substrate support assembly 220, is electrically coupled to the second RF generator assembly 254B. The second RF generator assembly 254B includes a second RF generator 250B that is coupled to a second RF matching circuit 253B and a second filter assembly 252B disposed within a second RF generator assembly 251B.

The second RF generator assembly 254B, which includes the second RF generator 250B and the second RF generator assembly 251B, is generally configured to deliver a desired amount of pulsed RF bias at a desired pulsing frequency to the substrate electrode 226 of the substrate support assembly 220 based on control signals provided from the system controller 208. During processing, the second RF generator assembly 254B is configured to deliver pulsed RF power (e.g., a pulsed RF signal) to the substrate electrode 226 disposed proximate to the substrate support 222, and within the substrate support assembly 220. The pulsed RF power delivered to the substrate electrode 226 is configured to ignite and maintain the processing plasma using the processing gases disposed in the processing volume 221 and fields generated by the pulsed RF power delivered to the substrate electrode 226 by the second RF generator 250B.

The system controller 208 generally includes a central processing unit (CPU) 295, memory 296, and support circuits 297. The CPU 295 may be one of any form of a general purpose processor that can be used in an industrial setting. The memory 296, or non-transitory computer-readable medium, is accessible by the CPU 295 and may be one or more of memory such as random access memory (RAM), read only memory (ROM), floppy disk, hard disk, or any other form of digital storage, local or remote. The support circuits 297 are coupled to the CPU 295 and may comprise cache, clock circuits, input/output subsystems, power supplies, and the like. The various methods disclosed herein may generally be implemented under the control of the CPU 295 by the CPU 295 executing computer instruction code stored in the memory 296 (or in memory of a particular processing chamber) as, for example, a software routine. When the computer instruction code is executed by the CPU 295, the CPU 295 controls the processing chambers to perform processes in accordance with the various methods.

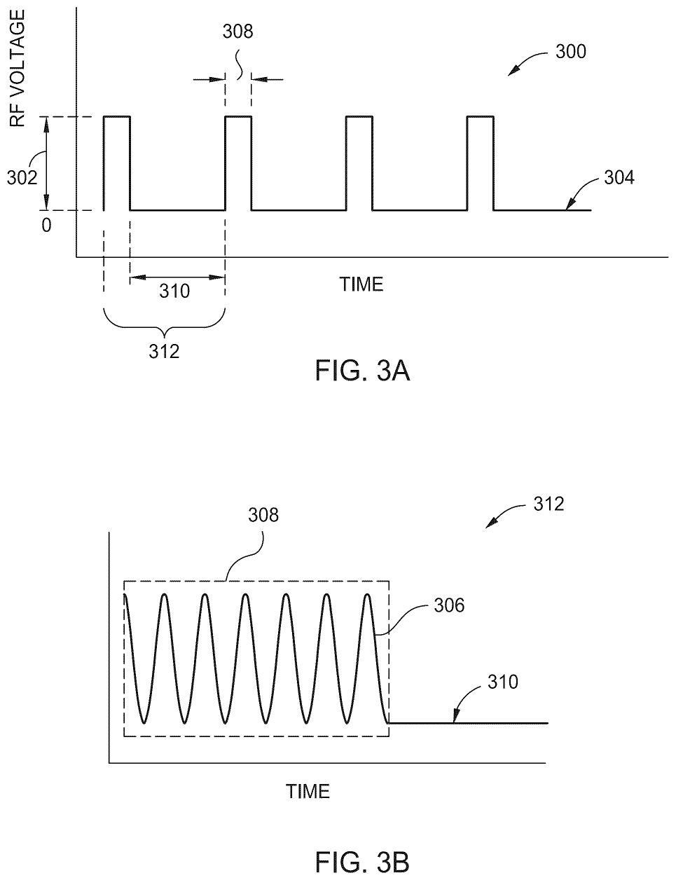

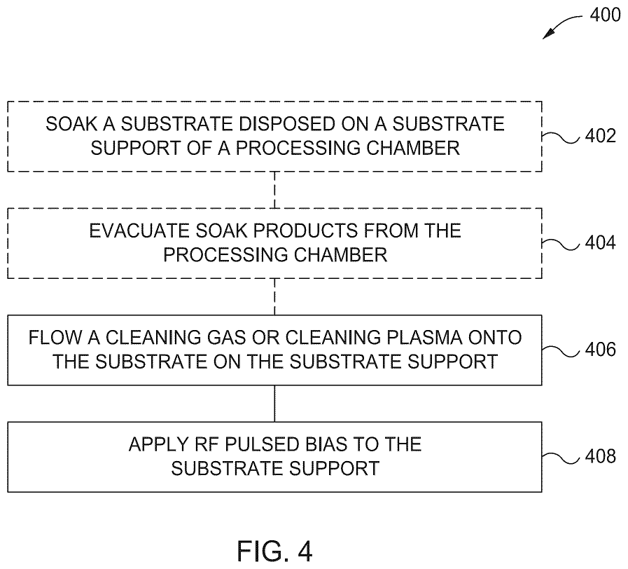

FIG. 3A illustrates a pulsing pattern generated by an RF generator assembly, e.g., the RF generator assembly 140 of FIG. 1 or the second RF generator assembly 254B of FIG. 2, according to certain embodiments. The pulsing pattern 300 includes a bias voltage 302 applied at an RF pulsed bias 304 over a pulse period 312. The pulse period 312 of the pulsing pattern 300 is defined as the frequency of switching between bias and no bias applied to the substrate support assembly 220. The pulse period 312 has a frequency that is about 10 Hz to about 40 kHz, such as about 100 Hz to about 1000 Hz. The RF pulsed bias 304 includes a first portion or bias ON period 308 and a second portion or bias OFF period 310 over a pulse period 312 of the pulsing pattern 300. The first portion or bias ON period 308 is where an RF waveform is delivered a substrate support assembly, e.g., the substrate support 104, and the second portion or bias OFF period is where delivery of the RF waveform is halted. The duration of the pulse period 312, e.g., the total duration of the bias ON period 308 and the bias OFF period 310 is determined by a pulsing frequency, e.g., how frequently the RF pulsed bias 304 is delivered. The pulsing frequency may be about 10 Hz to about 40000 Hz, resulting in the pulse period 312 having a duration of about 1/10 seconds to about 1/40000 seconds. For example, if a pulsing frequency of the pulsing pattern 300 is 100 Hz, the duration of the pulse period 312 would be about 0.01 seconds during which the RF bias waveform 306 is provided to an electrode (e.g., substrate electrode 106, 226).

As shown in FIG. 3B, the bias ON period 308 is a period where the bias voltage 302 is applied by use of an RF bias waveform 306, which can include, for example, a sinusoidal waveform that is provided at a frequency between 13.56 MHz and 27.12 MHz to the substrate support assembly 220, and the bias OFF period 310 is a period where the bias voltage 302 is not applied. The bias ON period 308 and the bias OFF period 310 cover the entirety of the pulse period 312 duration. The bias ON period 308 may have a duration that is between about 1% and about 99% of the pulse period 312, such as about 10% to about 80%, such as about 20% to about 50%. The bias OFF period 310 may have a duration that is consumes the remaining portion of the pulse period 312, such as about 99% to about 1%, such as about 90% to about 20%, such as about 80% to about 50%. For example, the pulse period 312 shown in FIG. 3A includes a bias ON period 308 with a duration of about 20% of the pulse period 312 and a bias OFF period 310 with a duration of about 80% of the pulse period 312. The pulse period 312 is then sequentially repeated for the duration of the treatment time of the chamber pre-clean process.

Pulsing the RF bias power delivered to the substrate support provides an additional tuning knob in a BEOL pre-clean process. When a cleaning gas or plasma, e.g., H₂, is supplied to the chamber, the bias ON period 308 energizes the hydrogen ions and attracts them toward the substrate, reducing the molybdenum oxide layers of the molybdenum structures on the substrate back to molybdenum. The duration of the bias ON period 308 affects the excitation of the ions with longer durations leading to higher excitation levels.

During the bias OFF period 310, the by-products of the redox reaction, e.g., H₂O, are allowed to leave the surface of the substrate unobstructed by energized hydrogen ions traveling toward the substrate support. Removing these by-products prevents re-oxidation of the molybdenum structures during or after each pulse period 312. This results in more of the molybdenum oxide layer being reduced to pure molybdenum, reducing contact resistance between the molybdenum structures and metal deposited in subsequent BEOL processes.

The combination of the bias ON period 308 and the bias OFF period 310 of the pulsing pattern 300 allows for tuning of the ion energy of the cleaning plasma, e.g., plasma 112 that is not possible when using a continuous wave (CW) RF bias. The average ion energy peak is lowered and, when combined with different pulse period 312 durations, allows for modulation of the ion energy of the plasma. The pulsing pattern 300 also reduces the reaction of the ions, e.g., the hydrogen ions, with carbon present in the underlying substrate, e.g., carbon-doped silicon dioxide layers (e.g., low-k layers) formed on a substrate, due to the lowered peak ion energy. The pulsing pattern 300 preserves the carbon content of the substrate which, in turn, preserves its dielectric constant.

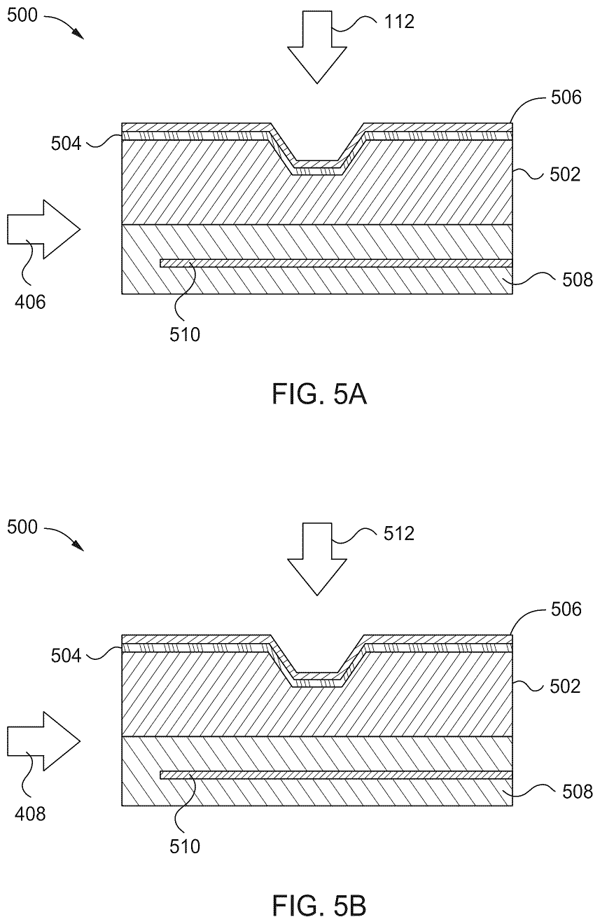

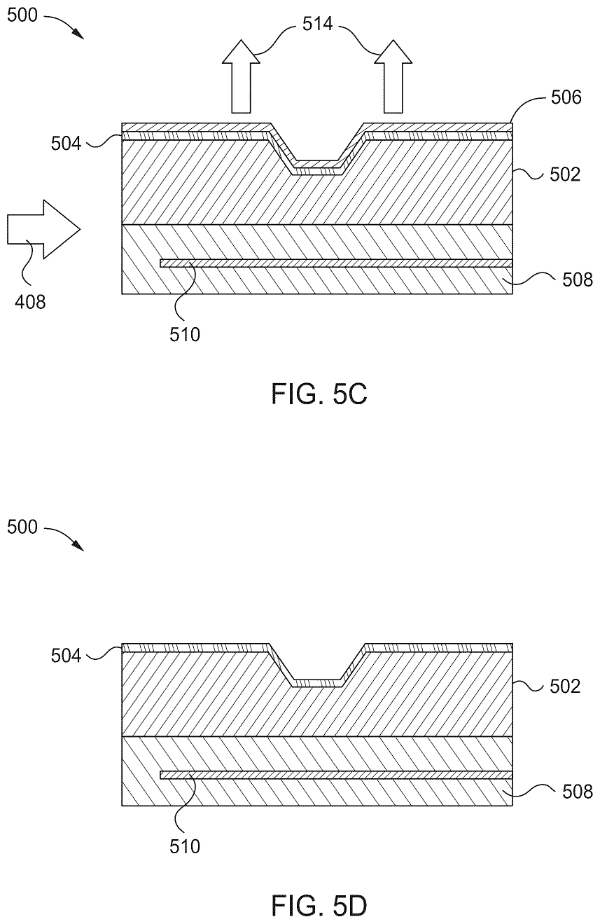

FIG. 4 illustrates a method 400 of removing a metal oxide, such as molybdenum oxide, during a BEOL pre-clean process, according to certain embodiments. In particular, the method 400 allows for improved reduction of a molybdenum oxide layer of molybdenum structures on a substrate. FIGS. 5A-5D illustrates a schematic, cross-sectional view of a substrate undergoing the method 400. The controller(s), e.g., the controller 160 and the system controller 208, discussed above are configured to execute the method 400 using the substrate processing system 100 of FIG. 1. Although the substrate processing system 100 is configured to function to produce an inductively-coupled plasma and is used in the description of the method 400 below, the method 400 is applicable to processing systems configured to produce a capacitively-coupled plasma, such as the substrate processing system 200 of FIG. 2, and processing systems configured with remote plasma sources.

The method 400 may begin with optional operation 402. In optional operation 402, a substrate having molybdenum containing structures may be exposed to a pretreat soak process for a soak period. The soak may include exposing the substrate to a soak fluid, such as deionized water vapor or other useful gas. The soak period may be about 1 second to about 20 seconds, such as about 5 seconds to about 10 seconds. The optional operation 402 is then followed by optional operation 404, where the soak products are evacuated from the processing chamber 102, such as through the gas exhaust 116, for an exhaust period. The exhaust period may be about 1 second to about 60 seconds, such as about 10 seconds to about 30 seconds. For example, when the soak fluid comprises deionized water, the exhaust period removes the deionized water from the processing chamber to prevent excess oxidation of the molybdenum structures.

In operation 406, a cleaning gas or cleaning plasma 112 is introduced to the processing chamber 102 and is directed toward the substrate 500 as shown in FIG. 5A. The cleaning gas or cleaning plasma 112 may be any suitable cleaning gas, such as hydrogen (H₂), and may include a carrier gas, such as helium (He), argon (Ar), or a combination thereof. The substrate 500 includes a substrate body 502 disposed on a substrate support 508 having a metal layer 504 with a metal oxide layer 506. The substrate support 508 includes a substrate electrode 510 and is configured similarly to the substrate support 104 of FIG. 1 and the substrate support assembly 220 assembly of FIG. 2. In operation 408, which occurs while the cleaning gas or cleaning plasma 112 is present in the processing chamber 102, an RF pulsed bias 304 that follows a pulsing pattern 300 that includes the RF bias waveform 306 is applied to the substrate support 104 by the RF generator assembly 140. Applying the RF pulsed bias 304 may include generating the RF pulsed bias 304 in an RF bias generator, e.g., RF bias generator 142, and synchronizing the RF pulsed bias 304 with the delivery of a second RF signal, e.g., the RF power source 108 coupled to the induction coil of FIG. 1 or the first RF generator assembly 254A coupled to the upper electrode of FIG. 2. The bias ON period 308 of the RF pulsed bias 304 energizes the ions 512 within the generated cleaning plasma 112, causing the ions 512 to strike the substrate as shown in FIG. 5B. When the ions 512 strike the substrate, the ions 512 cause a redox reaction with the metal oxide layer 506, such as a molybdenum oxide layer, of the metal layer 504, such as molybdenum structures, on the substrate. For example, if hydrogen is used to generate a cleaning plasma 112, the hydrogen ions bond to the oxygen atoms of the molybdenum oxide, producing pure molybdenum and by-products 514, namely H₂O. During the bias OFF period 310, the by-products 514, e.g., H₂O, produced by redox reaction evaporates from the surface of the substrate as shown in FIG. 5C. The pulse period 312 of the pulsing pattern 300 is then repeated as a subsequent bias ON period 308 re-energizes the hydrogen ions and another iteration of the redox reaction occurs. The pulse period 312 repeats for the duration of the treatment cycle to produce a substrate 500 without a metal oxide layer 506 on its metal layer 504 as shown in FIG. 5D. The duration of the treatment cycle may be about 1 second to about method 400 seconds.

The present disclosure provides for a back end of line pre-clean process with a pulsing pattern applied to an RF bias of a substrate support assembly. This pulsed bias results in an RF bias modulation that, when applied to the substrate support assembly by an RF generator, significantly expands the pre-clean process window while improving efficiency of molybdenum oxide reduction and reducing damage to the low-k material of the substrate, e.g., preserving its carbon content, which improves overall back end of line manufacturing. Further, the pulsed bias reduces contact resistance and resistance-capacitance delays, improving the electrical performance of the memory device.

In some embodiments, after performing the pre-clean process sequence, a deposition process can then be performed in a different processing chamber to deposit a conductive layer over the pre-cleaned surface of the metal layer 504, i.e., removing or reducing the metal oxide layers. In one example, the deposition process can include the use of a capacitively coupled plasma (CCP) plasma process performed in a plasma processing chamber that includes a showerhead that is configured to provide one or more process gases to a processing region of a plasma processing chamber. In some embodiments, the deposition process can include forming a metal liner/barrier and/or metal fill type of deposition process that is used to form a BEOL interconnect. In some embodiments, the deposition process can include liner/barrier deposition process that can include forming a tantalum (Ta), tantalum nitride (TaN), titanium (Ti), titanium nitride (TIN), cobalt (Co), or other useful barrier liner material by use of physical vapor deposition (PVD) process, chemical vapor deposition (CVD) process, plasma enhanced chemical vapor deposition (PECVD) process, atomic layer deposition (ALD) process, or plasma enhanced ALD (PEALD) process. In some embodiments, the deposition process can include forming a metal fill layer over the liner/barrier layer. The metal fill layer deposition process can include forming a copper (Cu) layer by use of physical vapor deposition (PVD) process, chemical vapor deposition (CVD) process, plasma enhanced chemical vapor deposition (PECVD) process, atomic layer deposition (ALD) process, or plasma enhanced ALD (PEALD) process.

Alternately, in some embodiments, the deposition process can include forming a metal fill deposition process can include a plasma deposition process in which a precursor gas, such as a molybdenum (Mo) containing precursor gas (e.g., MoCl₅), is added to a flow of a second gas to form a deposition gas. In some embodiments, the second gas will include the reducing agent containing gas (e.g., H₂) and an inert gas such as argon (Ar). The formed deposition gas is used to cause the formation of the metal layer, such as a molybdenum containing layer over the pre-cleaned surface. In some embodiments, the molybdenum containing precursor gas can include molybdenum pentachloride (MoCl₅) or a tungsten containing precursor gas that includes hexachloride (WCl₆). The metal layer formation process may be performed in the processing region of a plasma processing chamber for a time period between 0.5 and 10 seconds, such as about 3 seconds at a pressure between 2 and 50 Torr. In some embodiments of the multiple step metal capping layer formation process the substrate is maintained at a temperature between 300° C. and 500° C., while the processing region of the processing chamber is maintained at a pressure between 10 Torr and 300 Torr. The metal layer deposition process can be performed at a first RF power level at a first RF frequency between about 1 megahertz (MHz) and 120 MHZ (e.g., 13.56 MHz), such as between 50 W and 500 W. In other examples, the metal capping layer formation process can be an ALD deposition process or a pulsed CVD process (i.e., cycling a CVD process steps and purge steps).

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a processing chamber having a dielectric lid;
an inductive coil disposed about the dielectric lid and configured to generate a plasma within the processing chamber;
a substrate electrode embedded within a substrate support assembly disposed within the processing chamber;
a radio frequency (RF) generator assembly coupled to the substrate electrode; and
a controller coupled to the processing chamber and configured to:
flow a cleaning gas over a surface of a substrate support disposed within a processing chamber;
generate a radio frequency (RF) pulsed bias using an RF bias generator of the RF generator assembly, wherein the RF pulsed bias comprises delivering an RF waveform for a first portion of a pulse period and halting the delivery of the RF waveform for a second portion of the pulse period;
deliver an RF signal from an RF power source coupled to the inductive coil to form a plasma over the surface of the substrate support; and
apply the RF pulsed bias to the substrate electrode within the substrate support assembly while the plasma is present in the processing chamber.

2. The substrate processing system of claim 1, wherein the first portion of the RF pulsed bias comprises between about 10% and 80% of the pulse period.

3. The substrate processing system of claim 1, wherein the second portion of the RF pulsed bias comprises between about 10% and 80% of the pulse period.

4. The substrate processing system of claim 1, wherein the first portion comprises a bias ON period wherein the RF signal is applied to the substrate support and the second portion comprises a bias OFF period wherein no RF signal is applied to the substrate support.

5. The substrate processing system of claim 1, wherein the first portion of the pulse period causes a reaction between ions of the plasma and a metal oxide layer on a substrate disposed on the substrate support.

6. The substrate processing system of claim 5, wherein by-products of the reaction between the ions of the plasma and the metal oxide layer evaporate during the second portion of the pulse period.

7. The substrate processing system of claim 1, wherein a duration of the pulse period is between about 1/10 seconds to about 1/40000 seconds.

8. A substrate processing system, comprising:
a processing chamber configured to form a capacitively coupled plasma and comprising an upper electrode coupled to a first radio frequency (RF) generator assembly;
a substrate electrode embedded within a substrate support and facing the upper electrode;
a processing volume between the upper electrode and the substrate electrode;
a second RF generator assembly coupled to the substrate electrode; and
a controller coupled to the radio frequency generator assembly and configured to:
flow a cleaning gas over a surface of a substrate support disposed within a processing chamber;
deliver an RF signal from the first RF generator assembly coupled to the upper electrode to form a plasma over the surface of the substrate support;
generate an RF pulsed bias using an RF bias generator of the second RF generator assembly, wherein the RF pulsed bias comprises delivering an RF waveform for a first portion of a pulse period and halting the delivery of the RF waveform for a second portion of the pulse period; and
apply the RF pulsed bias to the substrate electrode within the substrate support while the plasma is present in the processing chamber.

9. The substrate processing system of claim 8, wherein the first portion of the RF pulsed bias comprises between about 10% and 80% of the pulse period.

10. The substrate processing system of claim 8, wherein the second portion of the RF pulsed bias comprises between about 10% and 80% of the pulse period.

11. The substrate processing system of claim 8, wherein the first portion comprises a bias ON period wherein a bias voltage is applied to the substrate support and the second portion comprises a bias OFF period wherein no bias voltage is applied to the substrate support.

12. The substrate processing system of claim 8, wherein the first portion of the pulse period causes a reaction between ions of the plasma and a metal oxide layer on a substrate disposed on the substrate support.

13. The substrate processing system of claim 12, wherein by-products of the reaction between the ions of the plasma and the metal oxide layer evaporate during the second portion of the pulse period.

14. The substrate processing system of claim 12, wherein a duration of the pulse period is between about 1/10 seconds to about 1/40000 seconds.

15. A method of processing a substrate, comprising:
flowing a cleaning gas or cleaning plasma onto a substrate disposed on a substrate support assembly of a processing chamber; and
applying a radio frequency (RF) pulsed bias to the substrate support assembly while the cleaning gas or cleaning plasma is present in the processing chamber, wherein the RF pulsed bias comprises delivering an RF waveform for a first portion of a pulse period and halting the delivery of the RF waveform for a second portion of the pulse period.

16. The method of claim 15, further comprising:
before flowing the cleaning gas or cleaning plasma, soaking the substrate with a soak fluid for a soak period; and
evacuating soak products from the processing chamber.

17. The method of claim 15, wherein the first portion of the RF pulsed bias comprises between about 10% and 80% of the pulse period.

18. The method of claim 15, wherein the second portion of the RF pulsed bias comprises between about 10% and 80% of the pulse period.

19. The method of claim 15, wherein a duration of the pulse period is between about 1/10 seconds to about 1/40000 seconds.

20. The method of claim 19, wherein the first portion of the pulse period causes a reaction between ions of the plasma and a metal oxide layer on a substrate disposed on the substrate support.
